(19) United States
(12) Patent Application Publication
(10) Pub. No.: US 2009/0166182 A1
(43) Pub. Date: Jul. 2, 2009

(54) METHOD FOR MANUFACTURING TUNNELING MAGNETORESISTIVE FILM

(75) Inventor: Kenji NOMA, Kawasaki (JP)

Correspondence Address: Fujitsu Patent Center;C/O CPA Global, P.O. Box 52050, Minneapolis, MN, 55402, US

(73) Assignee: FUJITSU LIMITED, Kawasaki (JP)

(21) Appl. No.: 12/340,743

(22) Filed: Dec. 22, 2008

(30) Foreign Application Priority Data
Dec. 27, 2007 (JP) 2007-335823

(51) Int. Cl. C23C 14/34

(52) U.S. Cl. 204/192.1

(57) ABSTRACT

According to an aspect of an embodiment, a method for manufacturing a tunneling magnetoresistive film includes: providing a substrate and a first ferromagnetic layer on the substrate; and depositing a barrier material on the first ferromagnetic layer by sputtering to a target material including an element having an atomic weight in the range of 14 to 27 under an atmosphere including Ne to form a barrier layer consisting essentially of an ionic crystal with a rock-salt structure. The method further includes providing a second ferromagnetic layer on the barrier layer.

### CROSS REFERENCE TO RELATED APPLICATIONS

This application is based upon and claims the benefit of priority from the prior Japanese Patent Applications No. 2007-335823 filed on Dec. 27, 2007, the entire content of which is incorporated herein by reference.

### BACKGROUND

1. Technical Field

This art relates to a tunneling magnetoresistive film which varies in electrical resistance in response to an external magnetic field.

2. Description of the Related Art

Examples of arts related to the tunneling magnetoresistive film are discussed in Japanese Laid-open Patent Publication No. 2006-80116, and W. H. Butler et al., “Spin-dependent tunneling conductance of Fe/MgO/Fe sandwiches”, Phys. Rev. B, vol. 63 (5), 054416 (2001).

The following films are under study: tunneling magnetoresistive films which are suitable for use in reproducing heads for hard disk drives (HDDs) and which have a ferromagnetic layer/barrier layer (insulating layer)/ferromagnetic layer structure. The symbol “/” is used herein to indicate that materials or layers separated thereby are adjacent.

In order to increase the recording density of HDDs, magnetoresistive films for use in reproducing heads reading recorded signals need to have an increased magnetoresistance change rate (MR ratio). In 2000, it was theoretically predicted that a tunneling magnetoresistive film including a barrier layer made of (001)-oriented magnesium oxide (MgO) would exhibit a magnetoresistance change rate of several hundred percent. In 2002, it was reported that a (001)-oriented MgO layer was formed by sputtering. Since then, reproducing heads including such tunneling magnetoresistive films have been investigated for practical use.

An MgO layer formed by sputtering using an MgO target and argon gas may have oxygen defects (see Patent Document 1). In the MgO layer having such oxygen defects, surplus Mg²⁺ ions can serve as carriers to generate an ohmic current. This may cause the following disadvantages in tunneling magnetoresistive films: current leakage, a reduction in magnetoresistance change rate, dielectric breakdown, and the like. Barrier layers will be thinner because reproducing heads will have low-resistance. If thin barrier layers with a large number of defects are used to manufacture tunneling magnetoresistive films, the tunneling magnetoresistive films probably have a reduced magnetoresistance change rate.

### SUMMARY

According to an aspect of an embodiment, a method for manufacturing a tunneling magnetoresistive film includes: providing a substrate and a first ferromagnetic layer on the substrate; depositing a barrier material on the first ferromagnetic layer by sputtering to a target material including an element having an atomic weight in the range of 14 to 27 under an atmosphere including Ne to form a barrier layer consisting essentially of an ionic crystal with a rock-salt structure; and providing a second ferromagnetic layer on the barrier layer.

### BRIEF DESCRIPTION OF THE DRAWINGS

FIG. 1 is a sectional view of a tunneling magnetoresistive film manufactured by a method according to an embodiment of the present invention.

FIG. 2 is a schematic view illustrating the crystal structure of MgO contained in a barrier layer placed in a tunneling magnetoresistive film manufactured by a method of an embodiment.

FIG. 3 is a schematic sectional view of a tunneling magnetoresistive film including a (001)-oriented MgO layer.

FIG. 4 is a schematic view illustrating oxygen defects caused during the formation of an barrier layer by sputtering.

FIG. 5 is a schematic view illustrating oxygen defects caused during the formation of an barrier layer by sputtering.

FIG. 6 is a graph showing the relationship between the MR ratio and RA of a tunneling magnetoresistive film prepared in each of Examples 1 to 5 and Comparative Example 1.

### DESCRIPTION OF THE PREFERRED EMBODIMENTS

An ordinary tunneling magnetoresistive film has a pinned magnetic layer/barrier layer/free magnetic layer structure in which a barrier layer (or an insulating layer) sandwiched between a pinned magnetic layer and a free magnetic layer. The pinned magnetic layer is located between the barrier layer and an antiferromagnetic layer and has a portion which is in contact with the barrier layer and which is not readily changed in magnetization by an external magnetic field. The barrier layer is insulative and has an energy barrier through which electrons can tunnel. The free magnetic layer is in contact with the barrier layer and can be freely changed in magnetization by an external magnetic field. The term “external magnetic field” used herein means a magnetic field sufficient to change the magnetization of the free magnetic layer, that is, a magnetic field of several ten oersteds or more.

The tunneling probability (tunneling resistance) of a ferromagnetic tunnel junction is known to depend on the magnetization of bilateral magnetic layers. That is, the tunneling resistance thereof can be controlled with a magnetic field. The tunneling resistance thereof is given by the following equation:

i. R=Rs+0.5ΔR(1−cos θ) (1)

wherein R represents the tunneling resistance and θ represents the angle of the magnetizations of the magnetic layers. When the magnetizations of the magnetic layers are parallel to each other (θ=0°), the tunneling resistance is small (R=Rs). When the magnetizations of the magnetic layers are anti-parallel to each other (θ=180°), the tunneling resistance is large (R=Rs+ΔR).

This is due to that electrons present in a ferromagnetic body are polarized. In usual, there are spin-up electrons (up-electrons) and spin-down electrons (down-electrons). Since equal numbers of up- and down-electrons are present in an ordinary nonmagnetic metal, the nonmagnetic metal has no magnetic properties. However, the number (Nᵤₚ) of up-electrons present in a ferromagnetic material is different from the number (N_{down}) of down-electrons present therein; hence, the ferromagnetic material has up or down magnetic properties.

For the tunneling of an electron, it is known that the electron tunnels with the spin state thereof maintained.

Therefore, if there is a vacancy in the electronic state of a tunnel destination, the electron can tunnel. However, if there is no vacancy in the electronic state of the tunnel destination, the electron cannot tunnel.

The rate of tunneling resistance change is given by the product of the polarizability of an electron source and that of the tunnel destination as expressed by Equation (2) below.

i. ΔR/Rs=2×P1×P2/(1−P1×P2) (2)

wherein Rs represents the tunneling resistance that arises when the magnetizations of the bilateral magnetic layers are parallel to each other, ΔR represents the difference between the tunneling resistance that arises when the magnetizations of the bilateral magnetic layers are parallel to each other and the tunneling resistance that arises when the magnetizations of the bilateral magnetic layers are anti-parallel to each other, the difference therebetween being dependent on a material for forming the bilateral magnetic layers, ΔR/Rs represents the rate of magnetoresistance change (the rate of tunneling resistance change, or MR ratio), P1 represents the polarizability of the electron source, and P2 represents the polarizability of the tunnel destination. The polarizability P is given by Equation (3) below and depends on the type of a ferromagnetic metal.

i. P=2(Nᵤₚ−N_{down})/(Nᵤₚ+N_{down}) (3)

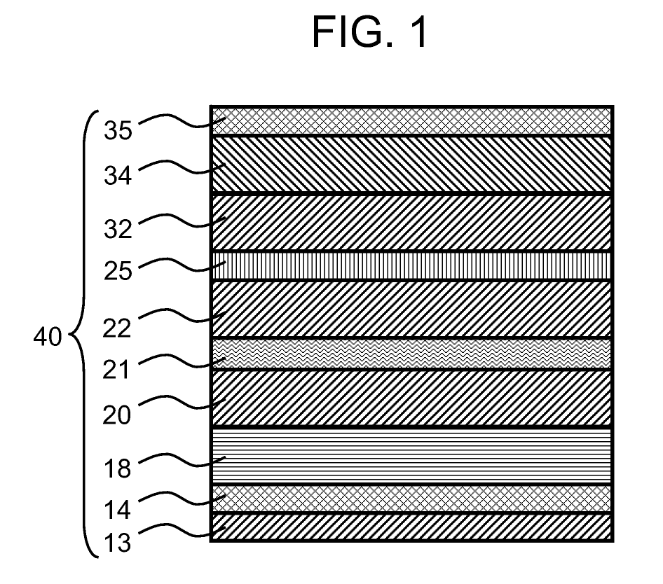

FIG. 1 is a sectional view of a tunneling magnetoresistive film 40 manufactured by a method according to an embodiment. The tunneling magnetoresistive film 40 includes a substrate (not shown), a first base layer 13, a second base layer 14, an antiferromagnetic layer 18, a first pinned magnetic layer 20, a nonmagnetic coupling layer 21, a second pinned magnetic layer 22, a barrier layer 25, a first free magnetic layer 32, a second free magnetic layer 34, and a capping layer 35, these layers being deposited on the substrate in that order.

In the tunneling magnetoresistive film 40 shown in FIG. 1, the first pinned magnetic layer 20, the nonmagnetic coupling layer 21, and the second pinned magnetic layer 22 each correspond to the above pinned magnetic layer, the barrier layer 25 corresponds to the above barrier layer, and the first free magnetic layer 32 and the second free magnetic layer 34 each correspond to the above free magnetic layer. In this embodiment, a first ferromagnetic layer is a pinned or free magnetic layer when a second ferromagnetic layer is a free or pinned magnetic layer, respectively.

The first base layer 13 is made of, for example, tantalum (Ta) and has a thickness of about 7 nm. The first base layer 13 may be copper (Cu) or gold (Au) or may include sublayers of these materials.

The second base layer 14 is made of, for example, ruthenium (Ru) and has a thickness of about 3 nm. The second base layer 14 functions as an orientation control layer for causing an iridium-manganese (Ir—Mn) alloy used to form the antiferromagnetic layer 18 to be (111)-oriented.

The antiferromagnetic layer 18 is made of the Ir—Mn alloy, which is an antiferromagnetic material, and has a thickness of about 7 nm. The antiferromagnetic layer 18 has a function of allowing the magnetization of a ferromagnetic material, such as a cobalt-iron (Co—Fe) alloy, used to form the first pinned magnetic layer 20 to be oriented by an exchange coupling magnetic field.

The first pinned magnetic layer 20 is made of the Co—Fe alloy, which a ferromagnetic material, and has a thickness of about 2 nm. The magnetization of the first pinned magnetic layer 20 is pinned in a predetermined direction by the exchange interaction with the antiferromagnetic layer 18. Even if an external magnetic field is applied to the first pinned magnetic layer 20, the first pinned magnetic layer 20 is not changed in magnetization when the external magnetic field is less than the exchange interaction.

The nonmagnetic coupling layer 21 is made of Ru and has a thickness of, for example, 0.8 nm. The thickness of the nonmagnetic coupling layer 21 is set such that the nonmagnetic coupling layer 21 is antiferromagnetically exchange-coupled with the second pinned magnetic layer 22. The thickness thereof preferably ranges from 0.4 to 1.5 nm and more preferably 0.4 to 0.9 nm.

The second pinned magnetic layer 22 is made of, for example, a ferromagnetic material such as a cobalt-iron-boron (Co—Fe—B) alloy and has a thickness of about 3 nm. The content of boron in the Co—Fe—B alloy is selected such that the Co—Fe—B alloy is amorphous or microcrystalline.

The magnetization direction of the first pinned magnetic layer 20 is antiparallel to that of the second pinned magnetic layer 22; hence, the net magnitude of the magnetic fields leaking from the first and second pinned magnetic layers 20 and 22 is low. Therefore, the following disadvantage is prevented: a disadvantage in that the magnetic fields leaking therefrom change the magnetization directions of the first and second free magnetic layers 32 and 34. This allows the magnetizations of the first and second free magnetic layers 32 and 34 to correctly respond to the magnetic field leaking from a magnetic recording medium, resulting in an increase in the accuracy of detecting magnetic signals recorded on the magnetic recording medium. The first pinned magnetic layer 20, the nonmagnetic coupling layer 21, and the second pinned magnetic layer 22 are referred to as a synthetic ferri-pinned layer.

The barrier layer 25 is made of, for example, magnesium oxide (MgO) and has a thickness of 0.5 to 1.0 nm. In the barrier layer 25, the (001) plane of MgO is preferably oriented substantially in parallel to the substrate. The term “(001)” used herein means that the (001) plane of a single crystal is oriented substantially in parallel to a substrate.

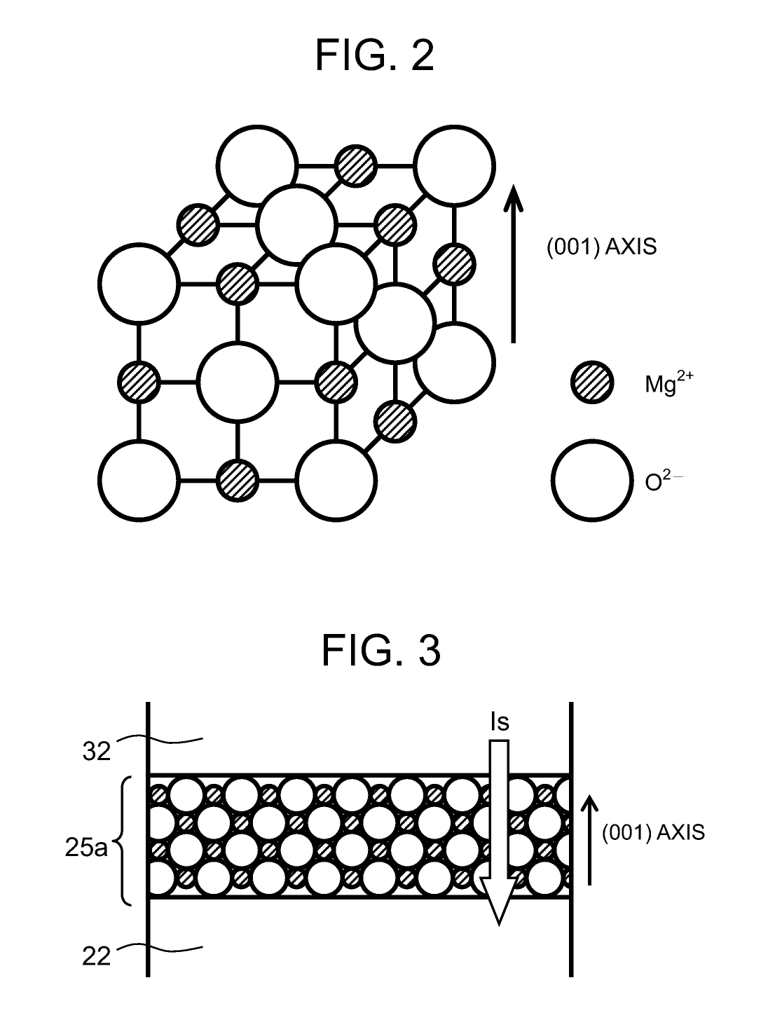

FIG. 2 is a schematic view illustrating the crystal structure of MgO contained in the barrier layer 25, which is placed in the tunneling magnetoresistive film 40 manufactured by the method of this embodiment. FIG. 3 is a schematic sectional view of a tunneling magnetoresistive film including a (001)-oriented MgO layer 25a. The radius of an Mg²⁺ ion is less than that of an O²⁺ ion; hence, FIGS. 2 and 3 schematically illustrate the difference in size between these ions. When a voltage is applied vertically to the MgO layer 25a in such a state that the magnetizations of a second pinned magnetic layer 22 and first free magnetic layer 32 sandwiching the MgO layer 25a are oriented in the same direction by the application of an external magnetic field, a sense current Iₛ flows along the (001) axis of MgO. When the MgO layer 25a contains ordered anions and cations and has no crystal axes other than the (001) axis, the sense current Iₛ is occupied by the resistance-free tunneling current generated by the coherent overlap of the propagation of mobile electrons with the electric potential generated by the (001) sequence of Mg²⁺ ions and O²⁺ ions. This allows magnetoresistance to be greatly enhanced. However, if the MgO layer 25a has crystal axes other than the (001) axis, sense currents flow along these crystal axes and therefore the above coherent overlap cannot be achieved. This leads to an increase in the percentage of an ohmic current in each sense current. The ohmic current deteriorates magnetoresistance.

A material for forming the barrier layer 25 is not theoretically limited to MgO. When the barrier layer 25 is made of a material which has a rock-salt structure and which can be (001)-oriented, the barrier layer 25 probably has a large magnetoresistance change rate. The rock-salt structure is characterized in that monovalent or divalent cations and anions are arranged at a ratio of 1:1 to form a lattice. The following compounds are known to have the rock-salt structure in addition to MgO: for example, LiF, NaF, NaCl, KCl, BeO, MgS, MgSe, CaO, SrO, BaO, and the like. Oxygen ions, fluorine ions, chlorine ions contained in these compounds are known to be relatively volatile because these ions form gaseous molecules.

The first free magnetic layer 32 and the second free magnetic layer 34 are freely changed in magnetization by an external magnetic field and produce magnetoresistance in cooperation with the synthetic ferri-pinned layers. The first free magnetic layer 32 is made of, for example, a ferromagnetic material such as a cobalt-iron (Co—Fe) alloy and has a thickness of about 1 nm. The second free magnetic layer 34 is made of, for example, a ferromagnetic material such as a nickel-iron (Ni—Fe) alloy and has a thickness of about 4 nm.

The capping layer 35 is made of, for example, tantalum (Ta) and has a thickness of about 5 nm. The capping layer 35 functions as a protective layer for preventing the oxidation of the first free magnetic layer 32 and the second free magnetic layer 34.

A method for manufacturing a tunneling magnetoresistive film according to an embodiment of the present invention will now be described.

A method for manufacturing the tunneling magnetoresistive film 40 shown in FIG. 1 is described below. The substrate (not shown) is prepared. The substrate is not particularly limited and may be a magnetic shielding substrate including, for example, a ceramic base plate made from an alumina-titanium-carbide mixture, an aluminum barrier layer disposed on the ceramic base plate, and a nickel-iron alloy layer disposed on the aluminum barrier layer. The magnetic shielding substrate may be patterned by a semiconductor process as required so as to have an appropriate pattern and a region other than the pattern may be covered with a nonmagnetic material. Examples of the substrate include Si substrates, Si substrates coated with SiO₂ layers, substrates made from various ceramic materials, and quartz glass substrates.

The layers from the first base layer 13 to capping layer 35 shown in FIG. 1 are formed on the substrate using a magnetron sputtering system. In order to form a multilayer film, targets each having the same composition as that of one of layers of the multilayer film are necessary. Since tantalum and ruthenium are used for deposition twice in this embodiment, at least eight pairs of tantalum and ruthenium targets are necessary. These targets are separately installed in vacuum chambers, which are connected to each other through vacuum conveying lines. A complex sputtering apparatus including the vacuum chambers is used.

An argon sputtering gas is usually used to form the layers from the first base layer 13 to the second pinned magnetic layer 22. Instead, a gas mixture of argon and krypton or xenon may be used as required depending on the type of each layer. If argon is used to form a layer of an iridium-manganese alloy, argon sputters manganese present in a surface portion of the layer because argon has an atomic weight less than that of iridium and therefore recoils. Therefore, the use of xenon, which has an atomic weight close to that of iridium, is effective in preventing argon from recoiling.

A sputtering gas used to form the barrier layer 25 from MgO is neon or a gas mixture of an inert gas and neon. The gas mixture may contain neon and argon. Magnesium, which is a heavy element contained in the barrier layer 25, has an atomic weight of 24.3; hence, neon is selected as a component of the sputtering gas because neon has an atomic weight of 20.2. The barrier layer 25, which is formed from MgO using the sputtering gas, is well oriented. This allows the tunneling magnetoresistive film 40 to have an increased magnetoresistance change rate. The reason for this phenomenon is not clear but is probably as described below.

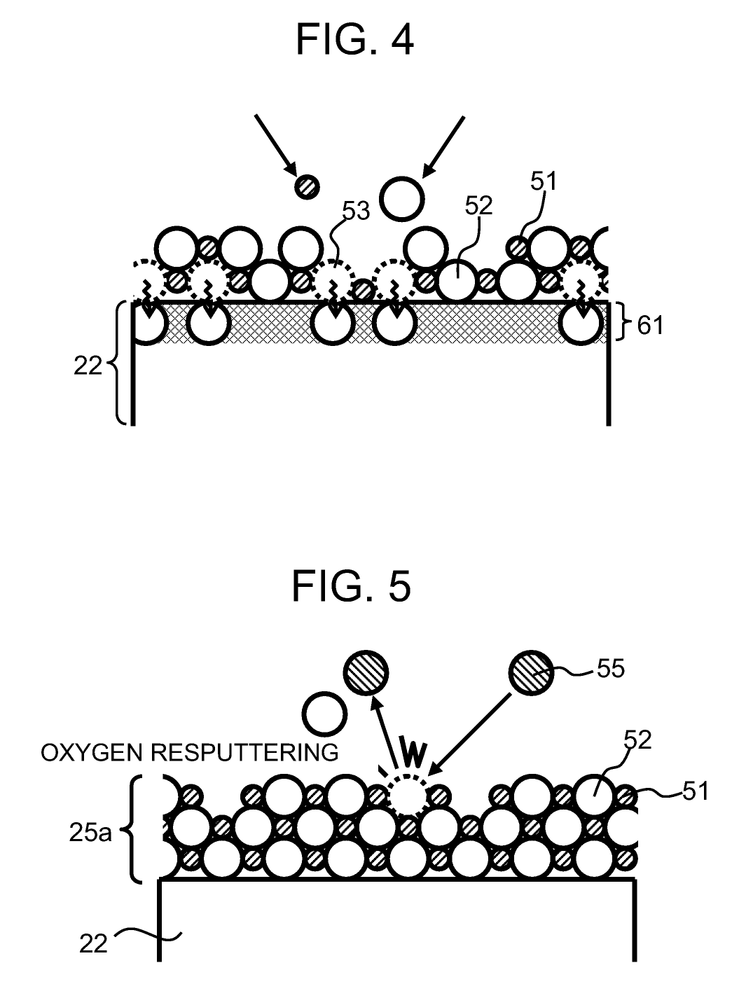

FIGS. 4 and 5 are schematic views illustrating oxygen defects caused in barrier layers formed by sputtering. In a tunneling magnetoresistive film, an MgO layer 25a is sandwiched between two ferromagnetic layers 22 and 32. The ferromagnetic layers 22 and 32 are conductive metal or alloy films. As shown in FIG. 4, metal atoms contained in a surface portion of the ferromagnetic layer 22 bond to oxygen atoms 52 contained in the MgO layer 25a; hence, a surface oxide region 61 is likely to be formed in the ferromagnetic layer 22 and oxygen-lacking portions 53 are likely to be formed in the MgO layer 25a. This prevents the MgO layer 25a from being stoichiometric. Furthermore, as shown in FIG. 5, recoiling atoms 55 that have elastically collided with a target impact a surface of the MgO layer 25a with a kinetic energy of several hundred electron volts. This allows the oxygen atoms 52 to be removed from the MgO layer 25a surface because the pressure of the oxygen atoms 52 is greater than that of magnesium atoms 51; hence, the oxygen-lacking portions 53 are increased. A technique for using oxygen gas during sputtering to compensate for such defects has been proposed; however, oxygen atoms released from a sputtering target have a kinetic energy of several electron volts and gaseous oxygen has a kinetic energy that is two or three orders of magnitude less than that of these oxygen atoms. Therefore, gaseous oxygen is hardly taken into the MgO layer 25a. That is, this technique is not effective in solving the problem that the MgO layer 25a is unsaturated. The recoiling atoms are described below in detail.

Various phenomena occurs during film formation by sputtering. Two of such phenomena are described below: one is a phenomenon occurring at a target surface and the other one is a phenomenon occurring at an barrier layer surface. These phenomena are described using an example in which film formation is performed in an ordinary argon atmosphere by sputtering an MgO target.

Phenomenon occurring at target surface

Table 1 summarizes the natures of species produced at a surface of the target during film formation. Argon atoms are ionized into argon ions, which are accelerated in an ion sheath present on the target and then impact the target with a kinetic energy of several hundred electron volts. In this moment, magnesium or oxygen atoms in the target are sputtered from the target by momentum exchange. The sputtered atoms consume a large amount of energy is consumed to break the bonds between the sputtered atoms and other atoms. Therefore, the sputtered atoms have a kinetic energy of several electron volts. Some of the sputtered atoms may be ionized in plasma by charge exchange, whereby magnesium ions (Mg⁺ and Mg²⁺) and oxygen ions (O₂⁺, O⁻, and O²⁻) are produced. Secondary electrons are emitted from the target by impacting during sputtering. The secondary electrons are negatively charged and therefore are accelerated in the ion sheath in the direction opposite to the incident direction of the argon ions to emerge therefrom with an energy of several hundred electron volts. Some of the incident argon ions that are not involved in sputtering elastically collide with the target to recoil with a kinetic energy of several hundred electron volts (recoiling atoms). Although the number of the recoiling atoms is small and is one hundredths of that of ions involved in sputtering, the recoiling atoms are negligible because the recoiling atoms have high energy and are emitted at random angles. In general, the greater the atomic weight of an element contained in a sputtering gas, the less the probability that the recoiling atoms are produced.

TABLE 1

| | | | EJECTION ANGLE | |
|---|---|---|---|---|
| PRODUCED | | DIRECTION OF | TO TARGET | |
| SPIECEIS | ENERGY | MOTION | SURFACE | REMARKS |
| ARGON ION | SEVERAL | FROM PLASMA | VERTICAL | Ar⁺ ION |
| | 100 eV | TO TARGET | | |
| MAGNESIUM | SEVERAL eV | EMITTING | RANDOM | MAGNESIUM IONS |
| ATOM | | DIRECTION | | MAY BE PRODUCED |
| | | FROM TARGET | | IN PLASMA. |
| OXYGEN | SEVERAL eV | EMITTING | RANDOM | OXYGEN IONS MAY BE |
| ATOM | | DIRECTION | | PRODUCED IN |
| | | FROM TARGET | | PLASMA. |
| SECONDARY | SEVERAL | FROM TARGET | VERTICAL | |
| ELECTRON | 100 eV | TO PLASMA | | |
| RECOIL ATOM | SEVERAL | EMITTING | RANDOM | |
| (ARGON) | 100 eV | DIRECTION | | |
| | | FROM TARGET | | |

Phenomenon occurring at barrier layer surface

The magnesium and oxygen atoms, which are emitted from the target, or ion species generated therefrom are bonded to each other, whereby crystals are grown. The molar ratio of magnesium to oxygen is preferably stoichiometric because rock-salt crystals of MgO are grown so as to be predominantly oriented in the (001) plane. However, some problems probably prevent the barrier layer from being stoichiometric.

A first problem is the contamination of other elements. This problem can be solved in such a manner that the purity of the sputtering gas is increased by increasing the purity and/or density of the target or another manner.

A second problem is that since the plasma formed in the sputtering gas is positively charged and therefore electrons leaking from the plasma cause a surface of the barrier layer during growth to be negatively charged, the magnesium ions, which are positively charged, are primarily deposited on the barrier layer surface. In order to prevent the barrier layer surface from being negatively charged, the potential of the plasma need to be reduced such that the bias voltage applied to the target is reduced. In general, the plasma potential can be reduced in such a manner that the average atomic weight of the sputtering gas is reduced such that the number of the secondary electrons emitted from the target is increased. Conversely, the use of a sputtering gas principally containing an element with an unnecessarily large atomic weight increases the negative charge of the barrier layer surface to cause lack of oxygen, which is not preferable.

A third problem is that the pressure of the oxygen ions is greater than that of the magnesium ions and therefore the barrier layer surface is likely to have oxygen defects. The recoiling atoms, which are incident on the barrier layer surface with an energy of several hundred electron volts, cause the barrier layer surface to be irregular and re-sputter magnesium and/or oxygen from the barrier layer surface. In particular, oxygen is more selectively re-sputtered because of its high vapor pressure. This can be a cause of the oxygen defects. In actual, a surface of the target also has oxygen defects during sputtering. However, this is not a serious problem, because an inner portion of the target is richer in oxygen than a surface portion thereof and therefore equal numbers of magnesium atoms and oxygen atoms are emitted from the target after a steady-state sputtering condition is achieved. On the other hand, if once oxygen atoms are removed from a surface portion of the barrier layer during growth, the barrier layer is lacking in oxygen because oxygen is not supplied from an inner portion of the barrier layer. The greater the difference in atomic weight between the sputtering gas (recoiling atom) and an element contained in the target, the more significant a shift in composition due to re-sputtering caused by one recoiling atom. From this viewpoint, the sputtering gas preferably has a small atomic weight. On the other hand, the fact that the atomic weight of the sputtering gas is less than that of the target element is likely to cause recoiling. Even if the re-sputtering probability of one recoiling atom is low, the number of the recoiling atoms is large and therefore the re-sputtering probability of the recoiling atoms is large. Therefore, it is not preferable that the atomic weight of the sputtering gas be excessively small.

Influences caused by selective re-sputtering can be probably reduced with high efficiency in such a manner that a sputtering gas having an atomic weight close to that of the target element is used.

In this embodiment, the above problems can be solved by specifying the relationship between the atomic weight of an element to be sputtered and the atomic weight of a sputtering gas used to form a barrier layer by sputtering. This probably allows an ideal stoichiometric (001)-oriented barrier layer to be formed even if MgO crystals contained therein have a size of 1 nm or less. The second and third problems occur in sputtering systems, particularly in diode glow discharge sputtering systems and magnetron sputtering systems.

It should be notated that the embodiment is characterized in the combination of a (001)-oriented layer having a rock-salt structure and a sputtering gas used to form the layer. In the past, there were some patents and scientific papers providing data for forming layers having a rock-salt structure using various sputtering gases. However, there is no patent or scientific paper specifying the relationship between the control of crystal orientation, the atomic weight of an element contained in a layer, and the atomic weight of a sputtering gas.

In this embodiment, the barrier layer made of MgO is formed by sputtering using the sputtering gas containing neon. In a manufacturing method according to the present invention, the composition of a sputtering gas and that of and an barrier layer are not limited to those described in this embodiment. In the present invention, film formation is performed by sputtering using an inert gas such as neon (Ne), krypton (Kr), or xenon (Xe) as an addition gas or a sputtering gas. The inert gas is hardly bonded to an element contained in a barrier layer (magnesium or oxygen contained in a barrier layer made of MgO). Therefore, an barrier layer formed by sputtering using the inert gas is likely to be stoichiometric. There are many substances that are gaseous at room temperature; however, gases containing a hydrogen atom, a nitrogen atom, an oxygen atom, a sulfur atom, and/or a halogen (fluorine, chlorine, bromine, or iodine) atom are unsuitable for forming an ion-crystalline barrier layer according to this embodiment and therefore are excluded. This is because these gases are tightly bonded to an element in an ion crystal, particularly magnesium or oxygen in the barrier layer made of MgO, and therefore the barrier layer is non-stoichiometric.

The kind of the inert gas is selected depending on an element contained in an barrier layer to be formed. When a barrier layer contains a binary compound, an inert gas having an atomic weight close to an element contained in the barrier layer is preferably used and an inert gas having an atomic weight close to a heavier element contained in the barrier layer is more preferably used.

In particular, when a heavier element contained in an ionic crystal has an atomic weight of 14 to 27, sputtering is performed in an atmosphere containing neon, which has an atomic weight of 20 and is close in atomic weight to the heavier element. The term “close in atomic weight to” used herein means that the difference in mass is less as compared to another inert gas. Examples of a compound suitable for sputtering performed in the neon-containing atmosphere include LiF, NaF, and BeO.

When the heavier element has an atomic weight of 65 to 96, sputtering is performed in an atmosphere containing krypton, which has an atomic weight of 84 and is close in atomic weight to the heavier element. Examples of a compound suitable for sputtering performed in the krypton-containing atmosphere include MgSe and SrO.

When the heavier element has an atomic weight of 112 to 184, sputtering is performed in an atmosphere containing xenon, which has an atomic weight of 131 and is close in atomic weight to the heavier element. An example of a compound suitable for sputtering performed in the xenon-containing atmosphere is BaO.

When the barrier layer is made of a ternary or higher-order compound, an inert gas used herein contains an element having an atomic weight close to that of an element that is the heaviest of elements which are contained in the barrier layer and which occupy 45% or more of the barrier layer. When the barrier layer is made of, for example, a compound prepared by adding about 1% to 2% of an element such as Zn, Cd, or Se to MgO, an element used as a standard for selecting the sputtering gas is selected so as to have an atomic weight close to that of Mg, which is selected from Mg and O contained in the barrier layer. The heaviest of the elements contained in the barrier layer is Zn, Cd, or Se; however, Zn, Cd, or Se is not used as a standard for selecting the sputtering gas because the probability that Zn, Cd, or Se is sputtered by the sputtering gas is less than the probability that Mg or O is sputtered by the sputtering gas.

The sputtering gas may contain at least one selected from inert gases such as neon (Ne), krypton (Kr), and xenon (Xe). The percentage of at least one selected from such inert gases in the sputtering gas is preferably 5% to 50% by volume because plasma is allowed to discharge stably.

Argon is usually used as a sputtering gas for forming the layers from the first free magnetic layer 32 to the capping layer 35 and krypton or xenon may be used to form these layers such that the MgO layer is prevented from being damaged by the impact of the recoiling atoms.

In this embodiment, the layers from the first base layer 13 to the capping layer 35 are formed on the substrate in that order. These layers may be formed on the substrate in the order from the capping layer 35 to the first base layer 13, that is, in the order reverse to the above.

After the formation of these layers is completed, the substrate is transferred from a vacuum chamber to air and then heat-treated in a vacuum such that an exchange coupling magnetic field generated from the antiferromagnetic layer 18 is increased. The heat-treating temperature and time of the substrate are selected to satisfy conditions for regulating the magnetization of the antiferromagnetic layer 18 and are, for example, about 200° C. to 300° C. and several hours. A direct-current magnetic field is applied to the substrate in the in-plane direction thereof during heating such that the magnetization of the first pinned magnetic layer 20 is fixed in a single direction. The magnitude of the magnetic field applied thereto may be sufficient to fix the magnetizations of the synthetic ferri-pinned layers in a single direction and is, for example, 1 T or more. Through the above steps, the tunneling magnetoresistive film 40 is obtained.

A tunneling magnetoresistive film with high magnetoresistance change rate can be manufactured by a method according to the embodiment, because an obtained barrier layer has a slight number of oxygen defects.

The present invention is not limited to the above embodiment. The above embodiment is for illustrative purposes only. The scope of the present invention covers any techniques having substantially the same configurations and advantages as those of techniques disclosed in the appended claims. A method according to the present invention is not limited to the manufacture of a magnetic head for HDDs but can be used to manufacture a magnetoresistive device such as a magnetoresistive random access memory (MRAM).

### EXAMPLES

### Example 1

Tunneling magnetoresistive films each including an MgO layer serving as a barrier layer were prepared by a tunneling magnetoresistive film-manufacturing method according to the present invention.

An alumina barrier layer and a magnetic shielding substrate made of a nickel-iron alloy were formed on a ceramic substrate made from an alumina-titanium-carbide mixture in that order.

The following layers were formed on the magnetic shielding substrate in this order: a first base layer of a 7 nm thick tantalum layer, a second base layer of a 3 nm thick ruthenium layer, an antiferromagnetic layer of a 10 nm thick iridium-manganese alloy layer, a first pinned magnetic layer of a 2 nm thick cobalt-iron alloy layer, a nonmagnetic coupling layer of a 0.8 nm thick ruthenium layer, and a second pinned magnetic layer of a 3 nm thick cobalt-iron-boron alloy layer. The MgO layer was formed on the cobalt-iron-boron alloy layer so as to have a thickness of 1 nm. The following layers were formed on the MgO layer in this order: a first free magnetic layer of a 1 nm thick cobalt-iron alloy layer, a second free magnetic layer of a 4 nm thick nickel-iron alloy layer, and a capping layer of a 5 nm thick tantalum layer.

The following targets and chamber were used to form the above layers: targets each having the same composition as that of one of the above layers and a vacuum chamber equipped with a magnetron sputtering system. A sputtering gas used to form the MgO layer was an argon-neon gas mixture. The total pressure of gases in the chamber was 0.06 Pa. The content of neon in the sputtering gas was 8% by volume. The thickness of the MgO layer was controlled by sputtering time. Argon gas was used to form the layers other than the MgO layer during sputtering.

Each tunneling magnetoresistive film member obtained by forming the above layers and substrates was heat-treated in air in such a manner that a magnetic field was applied to the tunneling magnetoresistive film member, whereby a tunneling magnetoresistive film of Example 1 was obtained.

The heat-treating temperature and time of the tunneling magnetoresistive film member were about 280° C. and four hours, respectively. The magnitude of the magnetic field applied thereto was 1 T.

The following films were prepared: tunneling magnetoresistive films including MgO layers having different thicknesses of 0.4 to 1.5 nm.

### Example 2

Tunneling magnetoresistive films of Example 2 were prepared in substantially the same manner as that described in Example 1 except that the content of neon in a sputtering gas used to form MgO layers was 16% by volume.

### Example 3

Tunneling magnetoresistive films of Example 3 were prepared in substantially the same manner as that described in Example 1 except that the content of neon in a sputtering gas used to form MgO layers was 33% by volume.

### Example 4

Tunneling magnetoresistive films of Example 4 were prepared in substantially the same manner as that described in Example 1 except that the content of neon in a sputtering gas used to form MgO layers was 50% by volume.

### Example 5

Tunneling magnetoresistive films of Example 5 were prepared in substantially the same manner as that described in Example 1 except that the content of neon in a sputtering gas used to form MgO layers was 66% by volume.

### Comparative Example 1

Tunneling magnetoresistive films of Comparative Example 1 were prepared in substantially the same manner as that described in Example 1 except that argon gas was used to form MgO layers during sputtering instead of the argon-neon gas mixture.

### Comparative Example 2

Tunneling magnetoresistive films of Comparative Example 2 were prepared in substantially the same manner as that described in Example 1 except that an argon-xenon gas mixture having a xenon content of 8% by volume was used to form MgO layers during sputtering instead of the argon-neon gas mixture.

### Comparative Example 3

Tunneling magnetoresistive films of Comparative Example 3 were prepared in substantially the same manner as that described in Example 1 except that an argon-xenon gas mixture having a xenon content of 16% by volume was used to form MgO layers during sputtering instead of the argon-neon gas mixture.

### Comparative Example 4

Tunneling magnetoresistive films of Comparative Example 4 were prepared in substantially the same manner as that described in Example 1 except that an argon-xenon gas mixture having a xenon content of 33% by volume was used to form MgO layers during sputtering instead of the argon-neon gas mixture.

### Comparative Example 5

Tunneling magnetoresistive films of Comparative Example 5 were prepared in substantially the same manner as that described in Example 1 except that an argon-xenon gas mixture having a xenon content of 50% by volume was used to form MgO layers during sputtering instead of the argon-neon gas mixture.

### Comparative Example 6

Tunneling magnetoresistive films of Comparative Example 6 were prepared in substantially the same manner as that described in Example 1 except that an argon-xenon gas mixture having a xenon content of 66% by volume was used to form MgO layers during sputtering instead of the argon-neon gas mixture.

Evaluation

The tunneling magnetoresistive films prepared in Examples 1 to 5 and Comparative Examples 1 to 6 were measured for magnetoresistance change rate (MR-ratio) and tunnel resistivity (RA, given by the product of the vertical resistance and cross-sectional area of a film). A twelve-terminal probe method, or a current-in-place tunneling (ClPT) method, was used to measure the films. The principle of the twelve-terminal probe method is described in Applied Physics Letter, vol. 83, No. 1, pp. 84-86 (2003) in detail. The magnetoresistance change rate of each film was determined with a scanning conductivity microscope, SPM-CIPTech™, available from Capres.

In a tunneling magnetoresistive film, an MgO layer having a small thickness has low RA and low MR-ratio. The resistor of an ordinary layer can be calculated from the equation R×A=ρ×l, wherein R represents the resistance of the layer, A represents the cross-sectional area of the layer, ρ represents the resistivity of the layer, and l represents the length of resistance and also corresponds to the thickness of the layer. This equation shows that RA decreases with a reduction in the layer thickness l, that is, RA is proportional to the layer thickness l. If all electrons form a tunneling current, the MR-ratio of the tunneling magnetoresistive film theoretically depends on the polarizability of the above free and pinned layers and is independent of the thickness of a barrier layer. In actual tunneling magnetoresistive films, lattice and/or oxygen defects present in barrier layers scatter electrons and therefore the MR-ratio of each barrier layer is less than the theoretical one. Conversely, a barrier layer having a larger MR-ratio has a smaller number of lattice defects and/or oxygen defects as compared to another barrier layer even if these barrier layers are the same in RA.

Measurement Results

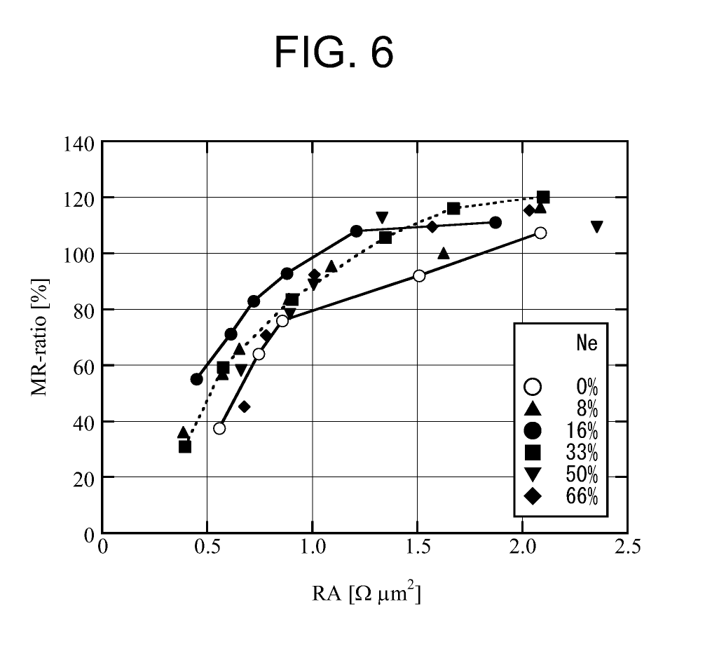

FIG. 6 is a graph showing the relationship between the MR ratio and RA of the tunneling magnetoresistive film of each of Examples 1 to 5 and Comparative Example 1. With reference to FIG. 6, the data of the tunneling magnetoresistive films of Comparative Example 1 is indicated by open circles, the tunneling magnetoresistive films including the MgO layers formed using argon gas. In the tunneling magnetoresistive films of Comparative Example 1, MR-ratio is 100% or more when RA is 2.1 Ωμm²; however, MR-ratio decreases linearly with a reduction in MgO layer thickness, that is, a reduction in RA and is less than 40% when RA is 0.6 Ωμm². In contrast, in the tunneling magnetoresistive films of Example 2 in which sputtering was performed using a gas mixture containing argon and 16% by volume of neon, MR-ratio is maintained at 110% in an RA range from a large value to 1.2 Ωμm² and is 70% when RA is 0.6 Ωμm². This shows that the effect of neon is about two times greater than that of argon. An increase in MR-ratio decreases with an increase in neon content. MR-ratio obtained at a neon content of 66% by volume is substantially equal to that obtained at an argon content of 100% by volume. This is probably because neon gas is less susceptible to discharge as compared to argon gas and therefore plasma is unstable.

Monolayer MgO films were prepared under the same sputtering conditions as those of each of Examples 1 to 5 and Comparative Example 1 and then analyzed by X-ray diffraction. As a result, the MgO film formed under the same sputtering conditions as those of Example 2 had a diffraction peak originating from the (001) plane and the intensity of this peak was largest. It was confirmed that a neon content less than or greater than 16% by volume reduced the intensity of a diffraction peak.

The above results show that a tunneling magnetoresistive film including a barrier layer made of MgO can be prepared so as to have high MR-ratio in a low RA range less than or equal to 2 Ωμm².

The tunneling magnetoresistive films prepared in Comparative Examples 2 to 6 using the argon-xenon gas mixtures as sputtering gases had an MgO deposition rate slightly less than that of the tunneling magnetoresistive films prepared using the argon-neon gas mixtures. The MgO layers, formed at any sputtering gas mixing ratio, having a relatively small thickness did not exhibit good insulation. The tunneling magnetoresistive films of Comparative Examples 2 to 6 had an RA of down to 10 Ωμm² and a small MR-ratio of about 50%. Monolayer MgO films were prepared under the same sputtering conditions as those of each of Comparative Examples 2 to 6 and then analyzed by X-ray diffraction. The analysis results showed that each MgO film had a diffraction peak originating from the (001) plane of MgO, the intensity of this peak was seriously small, and the MgO film had a large number of crystal defects.

These results probably arise since influences of re-sputtering are significant when a sputtering gas contains xenon, because xenon, which has a small collision cross sectional area, cannot efficiently supply kinetic energy to atoms present in a target and therefore sputtered atoms have low kinetic energy and because recoiling xenon atoms of which the number is less than that of neon or argon atoms and which have an excess energy of several ten electron volts impact a surface of a growing layer and xenon has a large mass.

What is claimed is:

1. A method for manufacturing tunneling magnetoresistance effect film comprising:
providing a substrate and a first ferromagnetic layer on the substrate;
depositing a barrier material on the first ferromagnetic layer by sputtering to a target material including an element having an atomic weight in the range of 14 to 27 under an atmosphere including Ne to form a barrier layer consisting essentially of an ionic crystal with a rock-salt structure; and
providing a second ferromagnetic layer on the barrier layer.

2. The method according to claim 1, wherein the barrier layer consisting essentially of a binary compound.

3. The method according to claim 1, wherein the binary compound is MgO.

4. The method according to claim 1, wherein the content ratio of the Ne in the atmosphere is 5 to 50 percent by volume.

5. A method for manufacturing tunneling magnetoresistance effect film comprising:
providing a substrate and a first ferromagnetic layer on the substrate;
depositing a barrier material on the first ferromagnetic layer by sputtering to a target material including an element having an atomic weight in the range of 65 to 96 under an atmosphere including Kr to form a barrier layer consisting essentially of an ionic crystal with a rock-salt structure; and
providing a second ferromagnetic layer on the barrier layer.

6. A method for manufacturing tunneling magnetoresistance effect film comprising:
providing a substrate and a first ferromagnetic layer on the substrate;
depositing a barrier material on the first ferromagnetic layer by sputtering to a target material including an element having an atomic weight in the range of 112 to 138 under an atmosphere including Xe to form a barrier layer consisting essentially of an ionic crystal with a rock-salt structure; and
providing a second ferromagnetic layer on the barrier layer.
